(19) United States
(12) Patent Application Publication
(10) Pub. No.: US 2026/0005111 A1
(43) Pub. Date: Jan. 1, 2026

(54) SEMICONDUCTOR PACKAGING METHOD, SEMICONDUCTOR PACKAGE AND ELECTRONIC DEVICE

(71) Applicant: Yibu Semiconductor Co., Ltd., Shanghai (CN)

(72) Inventor: Ming Li, Shanghai (CN)

(73) Assignee: Yibu Semiconductor Co., Ltd., Shanghai (CN)

(21) Appl. No.: 19/253,633

(22) Filed: Jun. 27, 2025

(30) Foreign Application Priority Data
Jun. 27, 2024 (CN) 202410849719.6

(51) Int. Cl. H01L 23/498; H01L 21/48; H01L 21/56; H01L 23/00; H01L 23/50; H01L 23/538; H01L 23/64; H01L 25/07

(52) U.S. Cl. CPC H01L 23/49811; H01L 21/4853; H01L 21/56; H01L 23/50; H01L 23/538; H01L 23/642; H01L 24/14; H01L 24/16; H01L 25/072; H01L 2224/1413; H01L 2224/16225

(57) ABSTRACT

A semiconductor packaging method, which utilizes a connection structure and an interconnection device to realize electrical connections between semiconductor devices and a power supply and the interconnection between the semiconductor devices. A capacitor is provided and is located on at least one side of the connection structure, and on at least one side of the interconnection device. Packaging the capacitor inside the semiconductor package and arranging it in a same layer as the connection structure and the interconnection device maintains the size of the semiconductor package, is conducive to miniaturization, shortens the distance between the capacitor and the semiconductor devices, and improving the effect of the capacitor in filtering high-frequency noise in the resulting circuit, which is conducive to improving the working stability of the semiconductor devices.

### CROSS REFERENCE TO RELATED APPLICATION

The present application claims the benefit of priority under the Paris Convention to Chinese Patent Application No. 202410849719.6, filed on Jun. 27, 2024, which is incorporated herein by reference in its entirety.

### TECHNICAL FIELD

The disclosure relates in general to the field of semiconductor technology, and particularly to a semiconductor packaging method, a semiconductor package and an electronic device.

### BACKGROUND

With the development of Integrated Circuit process technology, 2.5D and 3D System-In-Package (SIP) technologies are becoming increasingly mature, and multiple chips can be integrated by packaging.

In the related technology, a package structure integrating multiple chips is usually electrically connected to a printed circuit board and a system through a substrate, thereby realizing the connection between the chips and the system power supply. To filter out high-frequency noise and stabilize voltage, a capacitor is usually arranged near the chip package structure (for example, a place on the substrate adjacent to the chip package structure) to ensure normal operation of the chip. However, the capacitance of a single capacitor is small. To increase the capacitance, the number of capacitors needs to be increased, which increases the size of the entire semiconductor package and limits miniaturization. In addition, the horizontal distance between the capacitor and the chips limits the effect of the capacitor in filtering out high-frequency noise and stabilizing voltage.

### SUMMARY

To solve the above technical problems, the present disclosure provides a semiconductor packaging method, a semiconductor package and an electronic device, where a capacitor is arranged under the chips, resulting in shortened vertical distance between the capacitor and the chips, and improving the effect of the capacitor in filtering high-frequency noise and stabilizing voltage.

In a first aspect, the present disclosure provides a semiconductor packaging method, comprising providing carrier, a capacitor, an interconnection device, a first semiconductor device and a second semiconductor device are provided. The interconnection device comprises a first surface and a second surface arranged opposite to each other, the second surface comprises a first connection terminal, the first semiconductor device comprises a second connection terminal, and the second semiconductor device comprises a third connection terminal and a fourth connection terminal. The method further comprises:
forming a first connection structure on one side of the carrier;
forming a second connection structure on a side of the first connection structure facing away from the carrier;
attaching the capacitor to a side of the first connection structure facing away from the carrier;
attaching a first side of an interconnection device to the first connection structure;
attaching at least part of the second connection terminals to part of the first connection terminals;
attaching the third connection terminal to the remaining first connection terminals; and
attaching the fourth connection terminal to the second connection structure.

In some embodiments, the capacitor is located on at least one side of the second connection structure, the capacitor is located on at least one side of the interconnection device, the capacitor is electrically connected to the first connection structure, and the first connection structure is electrically connected to the second connection structure.

In some embodiments, the semiconductor packaging method further includes: forming a first molding layer. The first molding layer covers the first semiconductor device and the second semiconductor device, and also fills the gaps between the first semiconductor device and the first connection structure and between the second semiconductor device and the first connection structure.

In some embodiments, the semiconductor packaging method further includes: removing the carrier to expose the first connection structure.

In some embodiments, a fifth connection terminal is formed on a side of the first connection structure facing away from the second connection structure.

In some embodiments, the semiconductor packaging method further includes: providing a substrate. The substrate is attached to the fifth connection terminal.

In some embodiments, the semiconductor packaging method further includes; forming a second molding layer. The second molding layer fills the gaps between the first connection structure and the substrate.

In some embodiments, the semiconductor packaging method further includes: forming an external connection terminal on a side of the substrate away from the fifth connection terminal.

In some embodiments, the first connection structure comprises a redistribution layer, the redistribution layer comprises a metal layer and an insulator layer, and forming the first connection structure on one side of the carrier comprises:
forming a light-to-heat conversion layer on one side of the carrier;
forming a polymer layer on a side of the light-to-heat conversion layer facing away from the carrier; and
forming a seed layer on the side of the polymer layer facing away from the carrier.

In some embodiments, a metal layer and an insulator layer are formed on the side of the seed layer facing away from the carrier, and the metal layer penetrates the insulator layer in a direction perpendicular to the carrier where the carrier is located.

In some embodiments, the second connection structure includes a conductive pillar or a conductive bump.

In some embodiments, forming the second connection structure on a side of the first connection structure away from the carrier comprises:
coating a layer of photoresist on a side of the first connection structure facing away from the carrier;
forming an opening penetrating the photoresist, wherein the opening exposes the first connection structure;
forming the second connection structure in the opening; and
removing the photoresist.

In a second aspect, the present disclosure further provides a semiconductor package, which is packaged by the semiconductor packaging method described herein.

In a third aspect, the present disclosure further provides an electronic device, comprising the semiconductor package described herein.

Compared with the prior technology, the technical solution provided by the present invention has the following advantages. By encapsulating the capacitor inside the semiconductor package and setting it on the same layer as the second connection structure and the interconnection device, the size of the semiconductor package is not increased, which is conducive to miniaturization, and the distance between the capacitor and the semiconductor devices is shortened, thereby improving the effect of the capacitor in filtering high-frequency noise in the circuit, which is conducive to improving the working stability of the semiconductor devices.

### BRIEF DESCRIPTION OF THE DRAWINGS

The accompanying drawings, which are incorporated in and constitute a part of this specification, illustrate embodiments consistent with the disclosure and together with the description, explain the principles of the disclosure.

In order to more clearly illustrate the embodiments of the present disclosure or the solutions in the prior technology, the drawings that are required for the description of the embodiments or the prior technology will be briefly described below, and it will be obvious to those skilled in technology that other drawings can be obtained from these drawings without inventive efforts.

FIG. 1 is a schematic flowchart of a semiconductor packaging method provided by an embodiment of the present disclosure.

FIGS. 2 to 13 are schematic structural diagrams corresponding to various steps of the semiconductor packaging method provided by the embodiment of the present disclosure.

FIG. 14 is a schematic structural diagram of a semiconductor package provided by an embodiment of the present disclosure.

FIG. 15 is a schematic structural diagram of another semiconductor package provided in an embodiment of the present disclosure.

Following is a list of the reference numerals used in the drawings and their corresponding components according to some embodiments:
1. carrier;
11. photothermal-optical conversion layer;
12. polymer layer;
13. seed layer;
21. first connection structure;
22. second connection structure;
23. fifth connection terminal;
3. capacitor;
4. interconnection device;
41. first surface;
42. second surface;
43. first connection terminal;
44. bonding layer;
5. first semiconductor device;
51. second connection terminal;
6. second semiconductor device;
61. third connection terminal;
62. fourth connection terminal;
71. first molding layer;
72. second molding layer;
8. substrate;
9. external connection terminal.

### DETAILED DESCRIPTION OF THE EMBODIMENTS

In order to more clearly understand the above-mentioned objectives, features and advantages of the present disclosure, the scheme of the present disclosure will be further described below. It should be noted that the embodiments of the present disclosure and the features in the embodiments can be combined with each other without conflict.

In the following description, many specific details are set forth to facilitate a full understanding of the present disclosure, but the present disclosure may also be implemented in other ways different from those described herein. It is obvious that the embodiments in the specification are only part of the embodiments of the present disclosure, rather than all of the embodiments.

In the related technology, capacitors are usually arranged near a chip packaging structure to filter out high-frequency noise and stabilize voltage to ensure that the chip can work normally. The capacitors may include: on-chip capacitors arranged in the chip, package capacitors arranged on the substrate around the chip packaging structure, board capacitors arranged on the printed circuit board around the chip packaging structure, and bulk capacitors arranged on one side of the power module or power connector. However, the arrangement of such a large number of capacitors results in larger size of the semiconductor package, which is not conducive to the miniaturization of the semiconductor package.

In order to solve the above technical problems, the embodiments of the present disclosure provide a semiconductor packaging method, a semiconductor package and an electronic device, the semiconductor packaging method comprising: providing a carrier, a capacitor, an interconnection device, a first semiconductor device and a second semiconductor device. The interconnection device comprises a first surface and a second surface arranged opposite to each other, the second surface comprises a first connection terminal, the first semiconductor device comprises a second connection terminal, and the second semiconductor device comprises a third connection terminal and a fourth connection terminal, a first connection structure is formed on one side of the carrier, a second connection structure is formed on a side of the first connection structure away from the carrier, the capacitor is attached to a side of the first connection structure away from the carrier, the first surface of the interconnection device is attached to the first connection structure, at least part of the second connection terminal is attached to part of the first connection terminal, and the third connection terminal is attached to the remaining first connection terminal, and the fourth connection terminal is attached to the second connection structure. In some embodiments, the capacitor is located on at least one side of the second connection structure, and the capacitor is located on at least one side of the interconnection device, the capacitor is electrically connected to the first connection structure, and the first connection structure is electrically connected to the second connection structure. Therefore, by encapsulating the capacitor inside the semiconductor package and setting it on the same layer as the second connection structure and the interconnection device, the size of the semiconductor package is not increased, which is conducive to miniaturization, and the distance between the capacitor and the semiconductor device is shortened, thereby improving the effect of the capacitor in filtering high-frequency noise in the circuit, which is conducive to improving the working stability of the semiconductor device.

The semiconductor packaging method, semiconductor package and electronic device provided by the embodiments of the present disclosure are exemplarily described below with reference to the accompanying drawings.

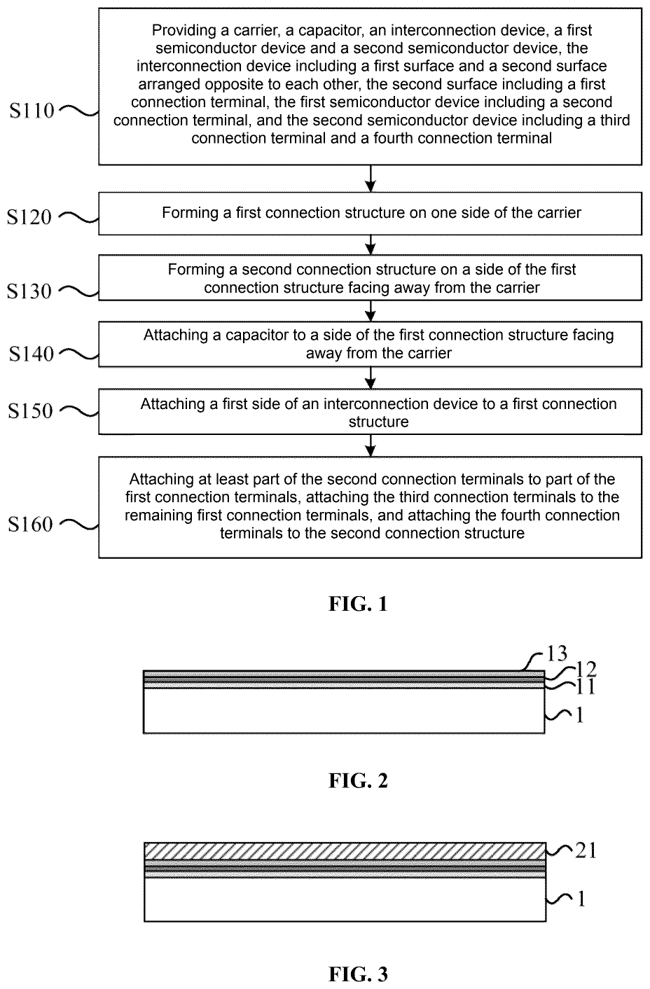

In some embodiments, as shown in FIG. 1, a schematic diagram of a semiconductor packaging method provided by an embodiment of the present disclosure is shown. Referring to FIG. 1, the semiconductor packaging method includes: S110, S120, S130. S140, S150, and S160, as described below.

S110, providing a carrier, a capacitor, an interconnection device, a first semiconductor device and a second semiconductor device. In some embodiments, the interconnection device includes a first surface and a second surface arranged opposite to each other, the second surface includes a first connection terminal, the first semiconductor device includes a second connection terminal, and the second semiconductor device includes a third connection terminal and a fourth connection terminal.

The embodiments of the present disclosure do not limit the type of the carrier 1, and all types of carriers known to those skilled in the technology may be used, such as a wafer carrier, a silicon-based carrier, a glass carrier, or a metal carrier.

The embodiments of the present disclosure do not limit the type, size and capacity of the capacitor 3. All types of carriers known to those skilled in the technology can be selected to set the capacity and size of the capacitor 3 according to requirements. For example, the capacitor 3 includes a silicon capacitor. In some embodiments, in a direction perpendicular to the carrier where the carrier 1 is located, the thickness of the capacitor 3 is less than or equal to 100 μm.

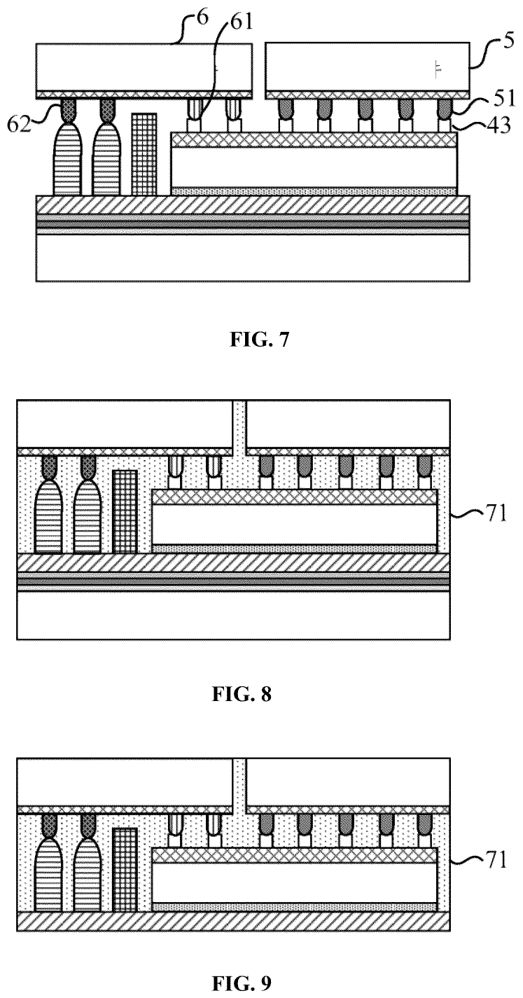

In this embodiment, semiconductor devices include, but are not limited to, wafers, dies and chips, and also include all types of semiconductor devices known to those skilled in the technology, which are not limited herein. Each semiconductor device includes a passive surface and an active surface arranged opposite to each other, and the active surface includes connection terminals, and the connection terminals include bumps and/or pads. As shown in FIG. 7, the semiconductor devices include a first semiconductor device 5 and a second semiconductor device 6, the active surface of the first semiconductor device 5 is provided with second connection terminals 51, and the active surface of the second semiconductor device 6 is provided with third connection terminals 61 and fourth connection terminals 62.

It should be noted that the embodiments of the present disclosure does not limit the type and quantity of the first semiconductor device 5 and the second semiconductor device 6. The types of the first semiconductor device 5 and the second semiconductor device 6 may be the same or different, which are not limited herein.

The embodiments of the present disclosure do not limit the type of interconnection device 4, and any device or structure with an interconnection function known to those skilled in the technology may be used, such as a silicon bridge (as shown in FIG. 6) or a structure with a conductive line layer on one side surface. The interconnection device 4 is used to realize the electrical connection between the first semiconductor device 5 and the second semiconductor device 6.

S120, forming a first connection structure on one side of the carrier.

With reference to FIG. 3, a first connection structure 21 is formed on the entire layer of one side of the carrier 1. The disclosed embodiment does not limit the type of the first connection structure 21, and the first connection structure 21 may be a metal layer, such as a copper layer. The first connection structure 21 may also be a redistribution layer, and the redistribution layer includes an insulator layer and a metal layer penetrating the insulator layer, that is, the metal layer is exposed on the surface of the insulator layer facing away from the carrier, so that the metal layer is electrically connected to the second connection structure and the capacitor in the subsequent steps.

S130, forming a second connection structure on a side of the first connection structure facing away from the carrier.

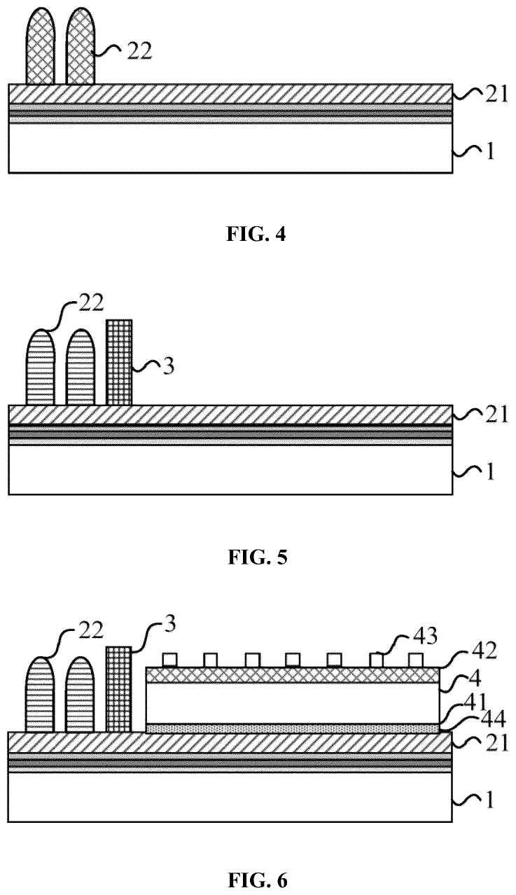

With reference to FIG. 4, the second connection structure 22 is located on a side of the first connection structure 21 away from the carrier 1, and the first connection structure 21 is electrically connected to the second connection structure 22.

The second connection structure 22 is a conductor. The embodiment of the present disclosure does not limit the shape of the second connection structure 22. The second connection structure 22 can be configured as a set of bumps, pillars, or pads.

S140, attaching a capacitor to a side of the first connection structure facing away from the carrier.

With reference to FIG. 5, the capacitor 3 is also located on the side of the first connection structure 21 facing away from the carrier 1, and is located on at least one side of the second connection structure 3. The capacitor 3 is electrically connected to the first connection structure 21.

S150, attaching a first side of an interconnection device to a first connection structure.

With reference to FIG. 6, 14 or 15, the interconnection device 4 is located on the side of the first connection structure 21 away from the carrier 1, and the capacitor 3 is located on at least one side of the interconnection device 4. A first surface 41 of the interconnection device 4 faces the first connection structure 21, a second surface 42 faces away from the first connection structure 21, and the second surface 42 is provided with first connection terminals 43.

The first side 41 of the interconnection device 4 can be attached to the first connection structure 21 via a bonding layer 44, or by soldering, for example, by forming a solder layer or bonding structure on the first side 41, which is not limited here.

S160, attaching at least part of the second connection terminals to part of the first connection terminals, attaching the third connection terminals to the remaining first connection terminals, and attaching the fourth connection terminals to the second connection structure.

With reference to FIG. 7, the active surface of the first semiconductor device 5 is directed toward the interconnection device 4, and at least part of the second connection terminals 51 are correspondingly attached to part of the first connection terminals 43, so that the first semiconductor device 5 is electrically connected to the interconnection device 4. The active surface of the second semiconductor device 6 is directed toward the second connection structure 22, whereby the third connection terminals 61 are attached to the remaining first connection terminals 43, and the fourth connection terminal 62 is attached to the second connection structure 22, so that the second semiconductor device 6 is electrically connected to the interconnection device 4 and the second semiconductor device 6 is electrically connected to the second connection structure 22. In this way, the electrical connection between the first semiconductor device 5 and the second semiconductor device 6 is achieved through the interconnection device 4, and the second semiconductor device 6 is electrically connected to the first connection structure 21 through the fourth connection terminals 62 and the second connection structure 22. The first connection structure 21 is used to connect an external device or a power source, thereby achieving the electrical connection between the first semiconductor device 5 and the second semiconductor device 6 and the external device or a power source.

As shown in any one of FIGS. 7, 14 and 15, in the structure of the semiconductor package obtained in this step, one or more capacitors 3 are arranged in the same layer as the second connection structure 22 and the interconnection device 4, and the interconnect device 4 is located between the first connection structure 21 and the first semiconductor device 5 (and/or the second semiconductor device 6), and the sum of the height of the second connection structure 22 and the height of the fourth connection terminal 62 is greater than or equal to the thickness of the capacitor 3. Thus, encapsulating the capacitor 3 in the semiconductor package does not increase the size of the semiconductor package, which is conducive to miniaturization. At the same time, the capacitor 3 is closer to the semiconductor device, shortening the distance between the capacitor 3 and the semiconductor device, improving the effect of the capacitor 3 in filtering high-frequency noise in the circuit, and is conducive to improving the working stability of the semiconductor device.

It should be noted that the embodiment of the present disclosure does not limit the shape of each connection terminal, and the shape of each connection terminal can be set according to requirements, such as a pad, a bump or a pillar.

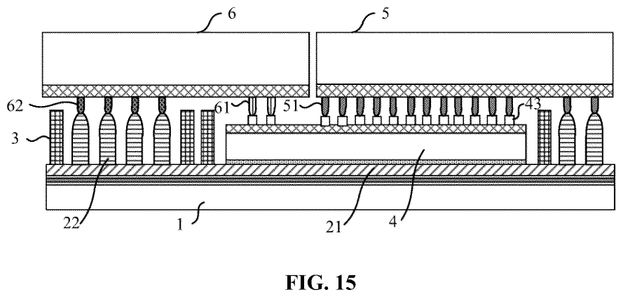

It should be noted that the embodiments of the present disclosure do not limit the location and the number of capacitors. The capacitor 3 may set away from the edge of the semiconductor package (as shown in FIG. 6), or a capacitor may be set near one side edge of the semiconductor package (as shown in FIG. 15), or capacitors may be set at all edges of the semiconductor package (as shown in FIG. 14), or one (or one row) of capacitors 3 may be set between the second connection structure 22 and the interconnection device 4 (as shown in FIG. 6), or two (or two rows) of capacitors may be set between the second connection structure and the interconnection device 4 (as shown in FIG. 14 or 15).

The semiconductor packaging method provided by the embodiment of the present disclosure encapsulates the capacitor 3 inside the semiconductor package so that it is arranged on the same layer as the second connection structure 22 and the interconnection device 4. This does not increase the size of the semiconductor package, which is conducive to miniaturization, and shortens the distance between the capacitor 3 and the semiconductor device, thereby improving the effect of the capacitor 3 in filtering high-frequency noise in the circuit, which is conducive to improving the working stability of the semiconductor device.

In some embodiments, the semiconductor packaging method further includes forming a first molding layer. The first molding layer covers the first semiconductor device and the second semiconductor device, and fills the gaps between the first semiconductor device and the first connection structure and between the second semiconductor device and the first connection structure.

In this embodiment, the first molding layer 71 is used to protect and reinforce the semiconductor package.

With reference to FIG. 8, the gaps between the first semiconductor device 5 and the first connection structure 21 and between the second semiconductor device 6 and the first connection structure 21 are filled with a package material, and a first molding layer 71 is formed after solidification. The first molding layer 71 fills the gaps between the first semiconductor device 5 and the interconnection device 4, and also covers the second connection structure 22, the capacitor 3, the third connection terminal 61 and the fourth connection terminal 62, and also covers the unoccupied surface of the first connection structure 21. The package material is also wrapped on the surface of the first semiconductor device 5 and the second semiconductor device 6. The first molding layer 71 formed after solidification not only fills the gaps between the first semiconductor device 5 and the second semiconductor device 6, but also at least partially covers the top surface (i.e., the side surface away from the first connection structure 21) and the side surface of the first semiconductor device 5 and the second semiconductor device 6. As shown in FIG. 8, the first molding layer 71 located on the top surface can also be removed by a grinding process.

The disclosed embodiment does not limit the material for preparing the first molding layer 71, and any package material known to those skilled in the technology can be selected, such as a molding compound of a resin material. Exemplarily, the first molding layer 71 is prepared using epoxy resin.

In some embodiments, the semiconductor packaging method further includes removing the carrier to expose the first connection structure, and forming a fifth connection terminal on a side of the first connection structure facing away from the second connection structure.

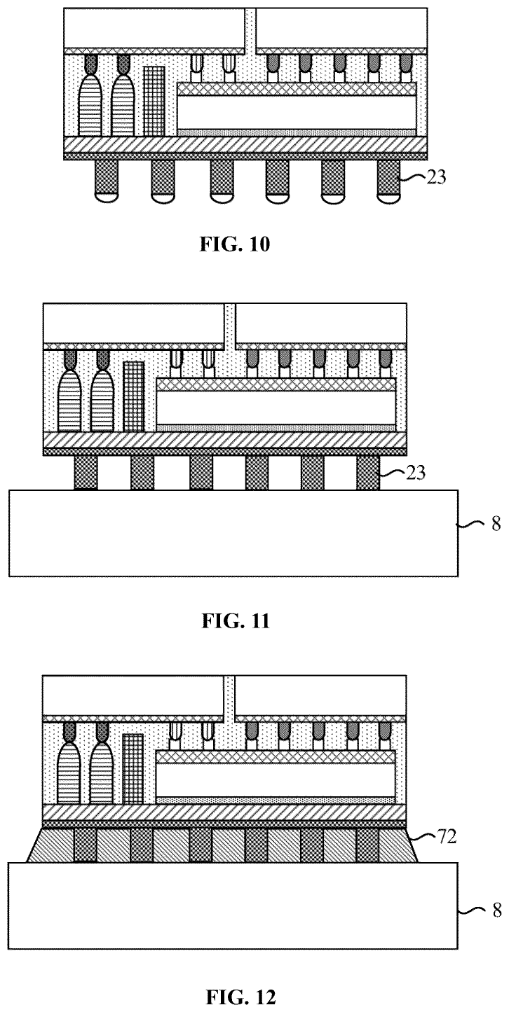

With reference to FIG. 9, the embodiment of the present disclosure does not limit the method of removing the carrier 1. The carrier 1 can be removed by an appropriate method according to the type of the carrier, including but not limited to at least one of laser debonding, thermal debonding, mechanical debonding, etching and grinding. After removing the carrier 1, the surface of the first connection structure 21 facing away from the second connection structure 22 is exposed.

With reference to FIG. 10, a fifth connection terminals 23 are formed on a side of the first connection structure 21 away from the second connection structure 22, and the fifth connection terminals 23 are electrically connected to the first connection structure 21. The fifth connection terminals 23 are used to connect an external device, including but not limited to a substrate, a power supply or a processor.

The embodiment of the present disclosure does not limit the shape of the fifth connection terminals 23, and the fifth connection terminals 23 may be configured as pads, bumps, and/or pillars.

In some embodiments, after “forming the fifth connection terminals”, the semiconductor packaging method further includes providing a substrate, and the substrate is attached to the fifth connection terminals.

As shown in FIG. 11, the substrate 8 is located on the side of the fifth connection terminal 23 away from the first connection structure 21. The substrate 8 includes, but is not limited to, an Ajinomoto Build-up Film (ABF) substrate and a Bismaleimide Triazine (BT) substrate, and also includes all types of substrates known to those skilled in the technology, which are not limited here.

In some embodiments, after “attaching the substrate to the fifth connection terminal”, the semiconductor packaging method further includes forming a second molding layer. The second molding layer fills the gaps between the first connection structure and the substrate.

As shown in FIG. 12, the second molding layer 72 fills the gaps between the first connection structure 21 and the substrate 8, and covers the fifth connection terminal 23. The second molding layer 72 may use a prepreg to cover the fifth connection terminal 23, and the prepreg includes a combination of one or more of epoxy resin, polyethylene, polypropylene, polyolefin, polyamide, polyurethane, etc. The second molding layer 72 may also use a liquid or powder epoxy resin or other material, which not only covers the fifth connection terminal 23, but also fills the gaps between the fifth connection terminals 23.

In some embodiments, after “forming the second molding layer”, the semiconductor packaging method further includes forming external connection terminals on a side of the substrate facing away from the fifth connection terminal.

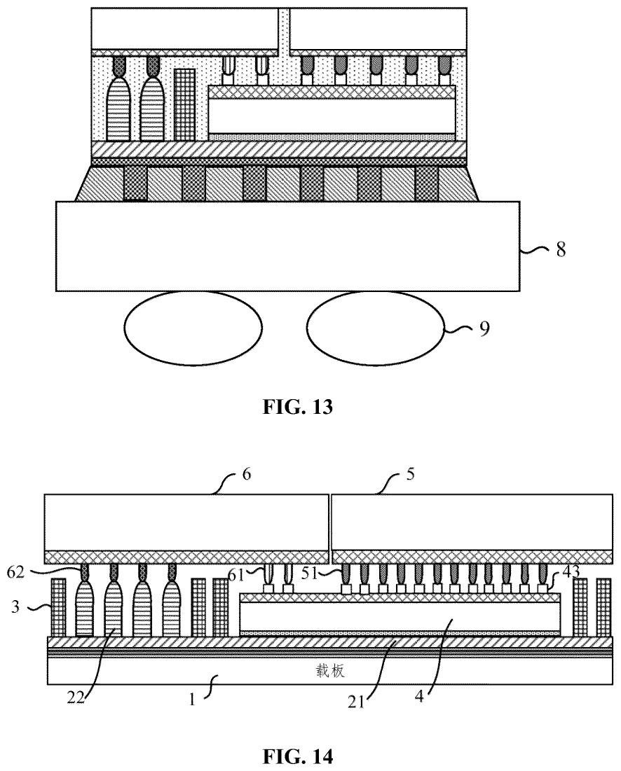

Referring to FIG. 13, through holes (not shown) are provided in the substrate 8 that penetrate the thickness thereof, and a conductive material fills in the through holes so that the fifth connection terminals 23 located above the substrate 8 are electrically connected to the external connection terminals 9 located below the substrate 8. The external connection terminals 9 are used to connect to an external device, such as a printed circuit board or a power supply.

In some embodiments, the first connection structure includes a redistribution layer, and the redistribution layer includes at least one metal layer and at least one insulator layer, and “forming the first connection structure on one side of the carrier” includes the following steps:
forming a light-to-heat conversion layer on one side of the carrier;
forming a polymer layer on a side of the light-to-heat conversion layer facing away from the carrier;
forming a seed layer on the side of the polymer layer facing away from the carrier; and
forming a metal layer and an insulator layer on the side of the seed layer facing away from the carrier, the metal layer penetrating the insulator layer in a direction perpendicular to the carrier where the carrier is located.

With reference to FIGS. 2-3, before forming the first connection structure 21, a release layer and a seed layer 13 are formed on one side of the carrier 1, and the release layer includes: a photothermal-optical conversion layer 11 and a polymer layer 12 sequentially arranged in a direction away from the carrier 1. Exemplarily, the seed layer 13 includes a Ti/Cu metal layer.

In this embodiment, the first connection structure 21 is a redistribution layer, and the redistribution layer includes a metal layer and an insulator layer. In a direction perpendicular to the carrier where the carrier 1 is located, the metal layer penetrates the insulator layer, and the metal layer is exposed on the surface of the insulator layer facing away from the seed layer 13, so that the second connection structure 22 and the capacitor 3 in the subsequent steps are electrically connected to the metal layer (or the first connection structure 21).

The embodiments of the present disclosure do not limit the number of metal layers and insulator layers in the redistribution layer, and can be flexibly set according to requirements.

In some embodiments, the second connection structure includes a conductive pillar or a conductive bump, and “forming the second connection structure on a side of the first connection structure facing away from the carrier” includes the following steps:
coating photoresist on a side of the first connection structure facing away from the carrier;
forming an opening penetrating the photoresist, wherein the opening exposes the first connection structure;
forming a second connection structure in the opening; and
removing the photoresist.

In this embodiment, the second connection structure 22 includes a conductor, and its shape can be conductive bumps or conductive pillars, such as copper pillars.

The specific steps of forming the second connection structure 22 can be as follows: a whole layer of photoresist is coated on the surface of the first connection structure 21 facing away from the carrier 1, opening are formed at specified positions by laser exposure and development, the openings penetrate the photoresist, and the first connection structure 21 at the bottom is exposed. The second connection structure 22 can be formed in the openings by electroplating or deposition process, the second connection structure 22 fills the openings, and finally the photoresist is removed

On the basis of the above-mentioned implementation manner, the embodiment of the present disclosure further provides a semiconductor component, which is packaged by any of the above-mentioned semiconductor packaging methods and has corresponding beneficial effects. To avoid repeated description, it is not repeated here.

On the basis of the above-mentioned implementation manner, the embodiment of the present disclosure further provides an electronic device, which includes the above-mentioned semiconductor component and has corresponding beneficial effects. To avoid repeated description, it is not repeated here.

It should be noted that, in this article, relational terms such as “first” and “second” are only used to distinguish one entity or operation from another entity or operation, and do not necessarily require or imply any such actual relationship or order between these entities or operations. Moreover, the terms “include”, “comprise” or any other variants thereof are intended to cover non-exclusive inclusion, so that a process, method, material or device including a series of elements includes not only those elements, but also other elements not explicitly listed, or also includes elements inherent to such process, method, material or device. In the absence of further restrictions, the elements defined by the sentence “comprise a . . . ” do not exclude the existence of other identical elements in the process, method, material or device including the elements.

The above description is only a specific embodiment of the present disclosure, so that those skilled in the technology can understand or implement the present disclosure. Various modifications to these embodiments will be apparent to those skilled in the technology, and the general principles defined herein may be implemented in other embodiments without departing from the spirit or scope of the present disclosure. Therefore, the present disclosure is not limited to the embodiments described herein, but will conform to the widest scope consistent with the principles and novel features disclosed herein.

What is claimed is:

1. A semiconductor packaging method, comprising:
providing a carrier, a capacitor, an interconnection device, a first semiconductor device and a second semiconductor device, wherein the interconnection device comprises a first surface and a second surface arranged opposite to each other, the second surface comprises a first connection terminal, the first semiconductor device comprises a second connection terminal, and the second semiconductor device comprises a third connection terminal and a fourth connection terminal;
forming a first connection structure on one side of the carrier;
forming a second connection structure on a side of the first connection structure facing away from the carrier;
attaching the capacitor to a side of the first connection structure facing away from the carrier;
attaching a first side of an interconnection device to the first connection structure;
attaching at least part of the second connection terminals to part of the first connection terminals, attaching the third connection terminal to the remaining first connection terminals; and
attaching the fourth connection terminal to the second connection structure;
wherein the capacitor is located on at least one side of the second connection structure, and the capacitor is located on at least one side of the interconnection device, the capacitor is electrically connected to the first connection structure, and the first connection structure is electrically connected to the second connection structure.

2. The semiconductor packaging method according to claim 1, further comprising:
forming a first molding layer, wherein the first molding layer covers the first semiconductor device and the second semiconductor device, and fills the gaps between the first semiconductor device and the first connection structure, and between the second semiconductor device and the first connection structure.

3. The semiconductor packaging method according to claim 2, further comprising:
removing the carrier to expose the first connection structure;
wherein a fifth connection terminal is formed on a side of the first connection structure facing away from the second connection structure.

4. The semiconductor packaging method according to claim 3, further comprising:
providing a substrate, and the substrate is attached to the fifth connection terminal.

5. The semiconductor packaging method according to claim 4, further comprising:
forming a second molding layer, wherein the second molding layer fills the gaps between the first connection structure and the substrate.

6. The semiconductor packaging method according to claim 5, further comprising:
forming an external connection terminal on a side of the substrate away from the fifth connection terminal.

7. The semiconductor packaging method according to claim 1, wherein the first connection structure comprises a redistribution layer, and the redistribution layer comprises a metal layer and an insulator layer, and wherein:
forming a first connection structure on one side of the carrier comprises:
forming a light-to-heat conversion layer on one side of the carrier;
forming a polymer layer on a side of the light-to-heat conversion layer facing away from the carrier;
forming a seed layer on the side of the polymer layer facing away from the carrier; and
forming a metal layer and an insulator layer on the side of the seed layer facing away from the carrier, wherein the metal layer penetrates the insulator layer in a direction perpendicular to the carrier where the carrier is located.

8. The semiconductor packaging method according to claim 1, wherein the second connection structure comprises a conductive pillar or a conductive bump, and wherein:
forming a second connection structure on a side of the first connection structure away from the carrier comprises:
coating a layer of photoresist on a side of the first connection structure facing away from the carrier. forming an opening penetrating the photoresist, wherein the opening exposes the first connection structure;
forming the second connection structure in the opening; and
removing the photoresist;

9. A semiconductor package made by the semiconductor packaging method according to claim 1.

10. An electronic device, comprising the semiconductor package according to claim 9.
